(19) United States
(12) Patent Application Publication
(10) Pub. No.: US 2012/0178074 A1
(43) Pub. Date: Jul. 12, 2012

(54) DIMENSIONALLY STABLE WHITE BOARD

(75) Inventors: Sean Rigby Brown, Orillia (CA); James G. Long, Bolton (CA); Jithesh Kumar Patel, Markham (CA); John Geoffery Walmsley, Barrie (CA); James Arthur Egan, Woodbridge (CA); Teresa Acs, Toronto (CA)

(73) Assignee: EGAN TEAMBOARD INC., Woodbridge (CA)

(21) Appl. No.: 13/345,326

(22) Filed: Jan. 6, 2012

Related U.S. Application Data
(60) Provisional application No. 61/431,747, filed on Jan. 11, 2011.

(51) Int. Cl. B43L 1/00; H05K 13/00

(52) U.S. Cl. 434/408; 29/592.1

(57) ABSTRACT

A dry erase whiteboard, or other writing or projection surface assembly, is formed from a backing substrate having a surface, and an inner conductive layer and an outer conductive layer supported by the surface of the substrate. A resistive layer is positioned between the inner conductive layer and the outer conductive layer. The resistive layer has an electrical resistivity that varies in response to mechanical deformation and/or stress to provide a variable effective resistance between the inner and outer conductive layers. The outer conductive layer can be immovably attached to a fixed frame, which is mounted to the substrate, in spaced apart relation to the inner conductive layer to define an air gap therebetween and a tensioning assembly can maintain the outer conductive layer in a tensioned state. Alternatively, the resistive layer is fixed directly to each conductive layer to provide a substantially air free environment therebetween.

### FIELD OF THE INVENTION

Embodiments of the present invention relate to an interactive writing surface and, preferably, a multipurpose writing and projection surface having a dimensionally stable construction.

### BACKGROUND OF THE INVENTION

Whiteboards, also commonly referred to as dry erase boards or erasable marker boards, have previously been fabricated from a dry erase surface mounted onto a rigid substrate, such as a laminate or polycarbonate. Originally used only as writing surfaces for erasable markers or pens, whiteboards have since been used also as projection screens. For example, in U.S. Pat. No. 5,361,164 and U.S. 2005/0112324, Rosenbaum et al. describe a dual dry erase outer surface and micro-roughened inner surface. The dry erase outer surface prevents inks from being trapped in the whiteboard writing surface, while the micro-roughened inner surface reduces gloss to make the writing surface more suitable for use as a projection surface simultaneously.

Another feature added to some whiteboard surfaces, often the dry erase surface, is contact sensitivity to convert the whiteboard into an interactive device. For example, by detecting pressure applied to the dry erase surface, the whiteboard can be converted into an input device for a computer system. One approach to providing touch sensitivity is described in U.S. 2008/0083602 by Auger et al. In their design, a first conductive layer is disposed on a support substrate and an insulating spacer is mounted generally about the periphery of the substrate. A second, pre-tensioned conductive layer overlies the first conductive layer under sufficient tension to form and maintain an air gap therebetween in the absence of applied pressure. However, when sufficient pressure is applied, the two conductive layers are brought into contact. Closure of an electrical circuit through the contact point can then be detected to register touch.

### SUMMARY OF THE INVENTION

In known white boards, the outer conductive layer may be mounted to an adjustable frame. Over time, the outer conductive layer may sag due to changes in the resilient characteristics of the outer conductive layer, variations in temperature and the like. If the outer conductive layer sags too much, then it may contact the inner conductive layer, thereby producing an unintended signal. Further, even if the outer conductive layer maintains its spacing from the inner conductive layer, a reduction in the tension of the outer conductive layer could cause the white board to be too touch sensitive resulting in unintentional signals being produced. The adjustable frame is provided with a tensioning mechanism such that the outer conductive layer may be re-tensioned to remove any sag and to maintain a desired spacing or air gap between the opposed inner and outer conductive layers.

In accordance with the described embodiments, there is provided a whiteboard having a simplified construction in which the provision of a variably resistive material between conductive layers eases requirements on any tensioning mechanism used to maintain the outer conductive layer at a pre-specified tension. In some cases, the air gap can be eliminated altogether along with the tensioning mechanism used to form and maintain the air gap. In other cases, an air gap can be formed even with the resistive material provided, but less tension is required and/or no tensioning mechanism is required, resulting in a simpler whiteboard construction and a lighter, more reliable and, potentially, thinner whiteboard.

According to one broad aspect, there is provided a dry erase whiteboard with a backing substrate having a surface, and an inner conductive layer and an outer conductive layer supported by the surface of the substrate. A resistive layer is positioned between the inner conductive layer and the outer conductive layer. To provide progressive touch capability, the resistive layer has an electrical resistivity that varies in response to mechanical deformation and/or mechanical stress, such as application of pressure, to provide a variable effective resistance between the inner and outer conductive layers. The resistive layer is secured to one or both of the inner and outer conductive layers.

A fixed frame (e.g., a frame having a plurality of frame members that are immovably positioned on the substrate and/or, optionally, connected together) can be mounted to the backing substrate, with the outer conductive layer immovably attached to the fixed frame in a spaced apart relation to the inner conductive layer and, optionally, defining an air gap therebetween. The outer conductive layer may be provided on a flexible substrate wherein the substrate is affixed to the frame. The substrate may be pre-tensioned or tensioned when applied to the frame, thereby providing a suitable surface for image projection and/or writing, such that the outer conductive layer is mounted tautly to the frame.

Alternately, any tensioning assembly known in the art may be provided as part of the frame and the outer conductive layer to maintain the outer conductive layer in a tensioned state, whether or not the outer conductive layer is pre-tensioned. Accordingly, the substrate may optionally be applied to the frame and the frame then adjusted to tension the substrate.

To provide a substantially air-free environment between the inner conductive layer and the outer conductive layer, the resistive layer may be secured to corresponding surfaces of one or both of the inner and outer conductive layers, such as being applied to one or both thereof, such as by screen printing the resistive layer thereon, or by means of an adhesive in whole or in part. Alternately, the resistive layer may be positioned adjacent or in a touching relationship with the inner and outer conductive layers.

Preferably the inner and outer conductive layers may be formed into multiple planar segments in close proximity to and electrically insulated from adjacent planar segments. The planar segments in the inner and outer conductive layers respectively are preferably positioned opposite one another (i.e., facing one another) with the planar segments of the inner and outer conductive layers forming, e.g., a spaced grid of squares, rectangles, diamonds or any other suitable quadrilateral or geometric shapes. With each planar segment independently addressed, local variation in the effective resistance between the inner and outer conductive layers is detectable on a per segment basis. This enables multi-touch capability for the whiteboard in which multiple concurrent touches are detectable.

According to another broad aspect, there is provided a method of assembling a dry erase whiteboard in which inner and outer conductive layers are provided and a resistive layer, formed from a material having an electrical resistivity that varies in response to mechanical deformation, is provided between the inner and outer conductive layers and is preferably applied to at least one of the inner conductive layer and the outer conductive layer. The inner conductive layer may then be mounted on a surface of the backing substrate, and the outer conductive layer may be secured in close proximity to the first conductive layer (e.g., by being mounted to a frame or mounted to the resistive layer) to provide an effective resistance between the inner and outer conductive layers that varies with the mechanical deformation of the resistive layer.

The resistive layer may be deposited (e.g., screen-printed) onto one of the inner and outer conductive layers, or it may be adhered to the other conductive layer to provide a substantially air free environment between the inner and outer conductive layers. The conductive layers can also each be deposited (e.g., screen printed, roll-coated, blade-coated, gravure-coated, slot and die coated) onto corresponding flexible layers.

### BRIEF DESCRIPTION OF THE DRAWINGS

For a better understanding of the present invention, and to show more clearly how it may be carried into effect, reference will now be made, by way of example, to the accompanying drawings, which show at least one preferred embodiment of the invention, and in which:

FIG. 1A is cross section of a writing and projection surface according to one embodiment of the invention;

FIG. 1B is cross section of a writing and projection surface according to another embodiment of the invention;

FIG. 1C is cross section of a writing and projection surface according to a further embodiment of the invention;

FIG. 2 is an enlarged portion of the center section of FIG. 1A;

FIG. 3 is a graph showing the relationship between resistance and applied pressure of an exemplary variably resistive layer;

FIG. 4A is a perspective view of an alternative embodiment, in which planar segments are used to provide multi-touch, pressure sensitivity;

FIG. 4B is a perspective view of the embodiment of FIG. 4A without a resistive layer shown;

FIG. 4C is a perspective view of a further alternative embodiment, in which planar segments are used to provide multi-touch, pressure sensitivity;

FIG. 4D is a perspective view of the embodiment of FIG. 4C without a resistive layer shown;

FIG. 4E is a top plan view of the embodiment of FIG. 4C; and,

FIG. 5 is a schematic drawing of an interactive whiteboard system according to another embodiment of the invention.

### DESCRIPTION OF THE PREFERRED EMBODIMENT

Pressure sensitive whiteboards formed using an air gap between two conductive layers, such as the configuration described by Auger et al., require a tensioning mechanism to maintain the air gap. If the tension in the outer conductive layer is too little, wrinkles and other deformities can appear in the writing surface of the whiteboard that cause poor tactile feel and that distort any images displayed on the whiteboard surface. This diminishes the usefulness of the whiteboard as a writing surface and/or a projection surface. Also, if the tension in the outer conductive is decreased even further, the two conductive layers could inadvertently come into contact and register a false touch.

At the same time, maintaining the outer conductive layer in its tensioned state exerts a force on the underlying substrate or lamination to which the whiteboard is mounted. Due to this applied force, the lamination must have a certain robustness to withstand the tensile strain on the outer conductive layer. Sometimes the force applied to the lamination due to tensioning causes the lamination to warp or otherwise torque or bend, which may again cause the writing surface to become wrinkled and may cause the whiteboard to become inoperable.

In either event, a complex tensioning mechanism or assembly involving spacers and/or tension screws to maintain the outer conductive layer at the proper tension may be required. Such a tensioning mechanism and its associated components has a generally high labor content and a high labor cycle time during assembly. Each of the potentially greater number of parts requires manual handling. Further, the tensioning mechanism is subject to failure that may compromise the utility of the whiteboard.

The pressure sensitivity of the writing surface is also limited to single-touch, binary input. Accordingly, the whiteboard either registers a “touch” (corresponding to contact made between the two conductive layers) or a “no touch” (corresponding to no contact made between the two conductive layers). Different strengths or degrees of touch are not recognized. There is also no distinct identification of multiple concurrent touches. Each of these factors limit the available form and number of input commands that be may be received into the whiteboard, resulting in a less intuitive input interface.

Embodiments of the present invention provide a whiteboard formed using a resistive layer positioned between two conductive layers. The resistive layer is formed from a material or materials having a resistivity that varies inversely with applied pressure. As will be described, inclusion of the resistive layer or layers permits increased dimensional stability to the whiteboard and allows for definition of a wider range of more versatile and more intuitive input commands.

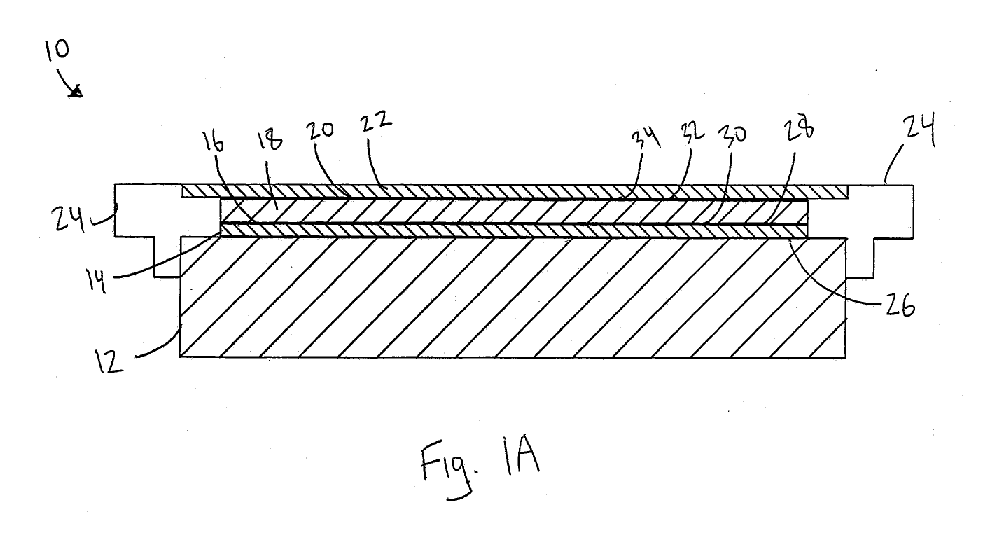

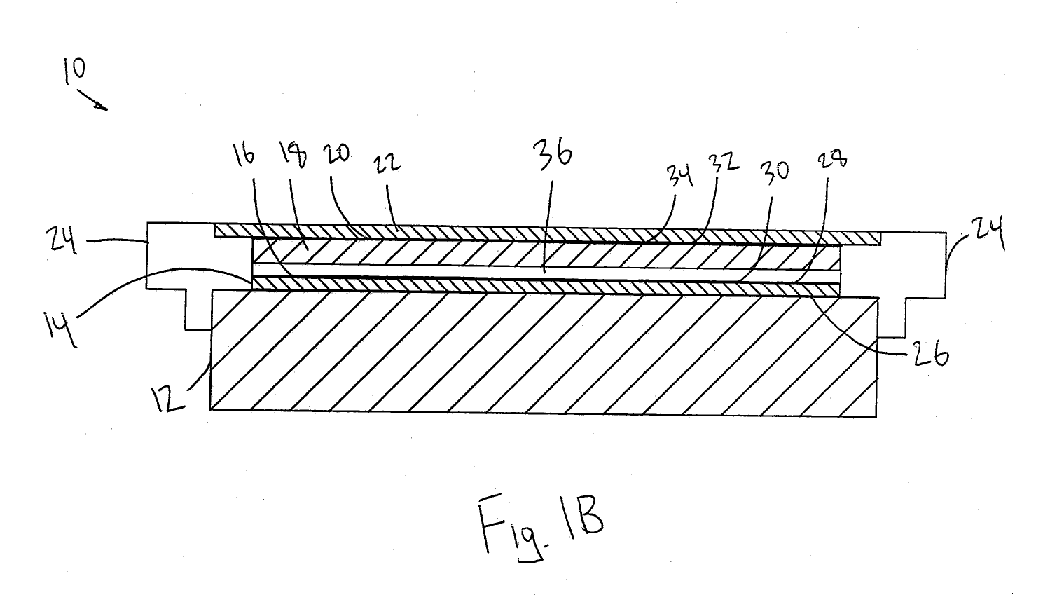

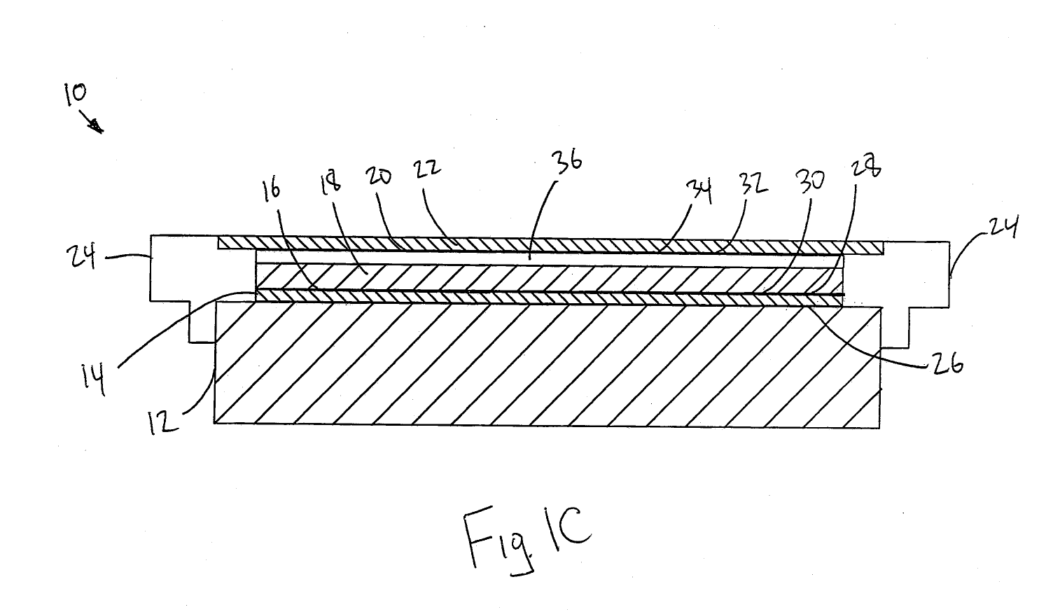

Referring now to FIG. 1A, there is shown an embodiment of a whiteboard 10. The whiteboard 10 has a backing substrate 12 on which is formed a number of layers, including an inner flexible layer 14, an inner conductive layer 16 (solid line), a resistive layer 18, an outer conductive layer 20 (solid line) and an outer flexible layer 22. The whiteboard 10 may be any size but, preferably, is a large scale whiteboard having a surface area of 500 square inches or more.

A peripheral frame 24 may optionally be mounted on the substrate 12 in some embodiments. The frame may comprise a plurality of frame members that are immovably secured together to define a frame having fixed dimensions so as to define a fixed peripheral frame. In other embodiments, a tensioning mechanism may be provided with the frame to define an adjustable peripheral frame.

The backing substrate 12 may be any suitable substrate known in the art for providing backing support for the whiteboard, such as a lamination or polycarbonate. For example, the backing substrate 12 permits the whiteboard 10 to be self-supporting or, in some cases, wall mountable. Accordingly, if the whiteboard 10 is wall mounted, the backing substrate 12 provides sufficient rigidity. The backing substrate 12 has an outer surface 26 on which the inner flexible layer 14 is supported.

The inner flexible layer 14 may be secured to the outer surface 26 of the backing substrate 12 by any means known in the art, such as by using an adhesive (e.g., a pressure sensitive adhesive). The inner flexible layer 14 may be made from any material known in the art. Preferably, the inner flexible layer 14 is made of a flexible polyester or polymer material. The inner flexible layer 14 has an outer surface 28 on which the inner conductive layer 16 is applied. In some embodiments, the inner flexible layer 14 may be replaced with a rigid or semi-rigid layer, or may be omitted altogether.

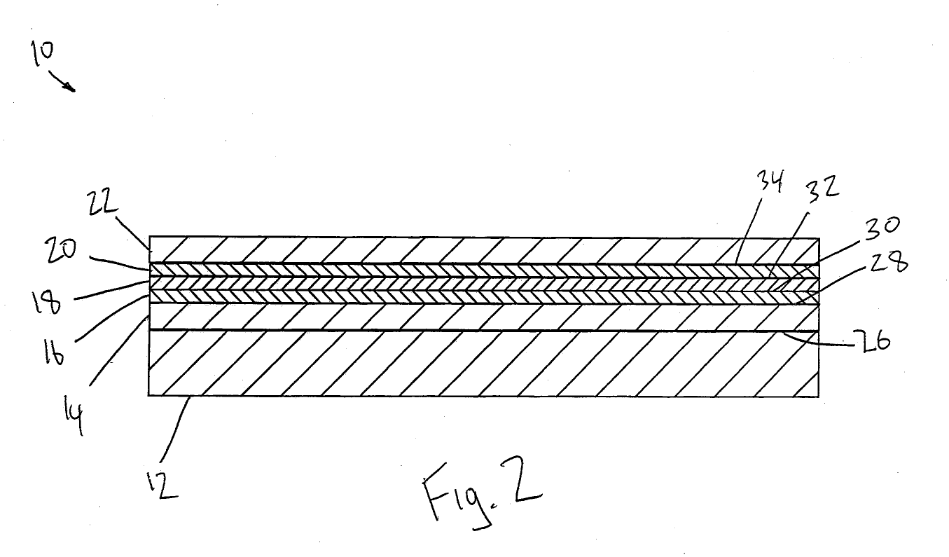

The inner conductive layer 16 may be provided on the inner flexible layer 14 by any means known in the art and may be of any composition known in the art. Preferably the inner conductive layer 16 is deposited onto the inner flexible layer 14, for example, as a screen-printed liquid and then cured to harden or by roll printing. The inner conductive layer 16 may be formed from a carbon composite material, or another conductive material, for this purpose. An outer surface 30 (shown more particularly in FIG. 2) of the inner conductive layer 16 opposes the resistive layer 18.

As exemplified in the embodiment of FIG. 1A, a pressure sensitive composite layer may comprise the resistive layer 18 that is sandwiched between the inner conductive layer 16 and the outer conductive layer 20 and is in touching relationship therewith. The inner surface of the resistive layer is optionally fixed to the outer surface 30 of the inner conductive layer 16, and an outer surface of the resistive layer is optionally fixed to an inner surface 32 of the outer conductive layer 20. The resistive layer 18 may be screen-printed or otherwise deposited onto either the inner conductive layer 16 or the outer conductive layer 20. The resistive layer 18 may then be secured immediately adjacent the other of the conductive layers 14 and 20 on which the resistive layer 18 is not deposited so as to cause light contact, but without exerting undue pressure that would change the electrical characteristics of the resistive layer as described below. Thereby a substantially air free environment is formed between the inner conductive layer 16 and the outer conductive layer 20.

The resistive layer 18 is made from a material having a resistivity (or equivalently a conductivity) that varies with applied pressure. For example, the resistivity of the resistive layer 18 may vary inversely with applied pressure, thereby to act as a substantial insulator when no pressure is applied, but act like an increasingly efficient conductive as the applied pressure increases. Accordingly, the effective resistance through the resistive layer 18, from the inner conductive layer 16 to the outer conductive layer 20 is preferably large when the resistive layer 18 is in a quiescent state and, most preferably, so is the signal produced in this state.

As a non-limiting example, the resistive layer 18 may be a variable resistivity ink or liquid polymer such as is described U.S. 2010/0062148A, U.S. Pat. No. 7,301,435 or PCT Application No. WO2008/135787A1 by Lussey, the disclosure of which is incorporated herein by reference. Force sensitive resistors may also be used.

The outer conductive layer 20 may be the same or different to the inner conductive layer 16 and may be applied to the inner surface 34 of the outer flexible layer in the same or a different manner. For example, the outer conductive layer 20 may be deposited or screen-printed onto the outer flexible layer 22, which may be flexible for that purpose. Like the inner conductive layer 16, the outer conductive layer 20 may be formed from a carbon composite material or other conductive material.

The outer flexible layer 22 is optionally mounted to a frame, which may be a fixed or adjustable peripheral frame 24 in some embodiments, although this is not necessary. Alternately, or in addition, the outer flexible layer 22, with the outer conductive layer 20 applied thereon, may be adhered directly to the resistive layer 18. The outer flexible layer 22 may be a polyester or flexible polymer layer. Although not shown, a dry erase coating may be applied, in some cases in combination with additional layers also not shown, to provide a dual writing and projection surface for the whiteboard 10. However, the dry erase coating is preferably a single layer.

Referring now to FIG. 1B, there is shown an alternative embodiment of the whiteboard 10 shown in FIG. 1A comprising an air gap 36. In the embodiment shown in FIG. 1B, the outer conductive layer 20 is preferably attached to the peripheral frame 24, by way of the outer flexible layer 22, to be held in a spaced apart relation with respect to the inner conductive layer 16. The resistive layer 18 does not fill the space between the inner conductive layer 16 and the outer conductive layer 20 to form the air gap 36.

In some cases, the outer conductive layer 20 is tensioned to maintain the air gap 36. For example, the outer flexible layer 22 may be mounted tautly to the peripheral frame 24 to maintain the outer conductive layer 20 formed thereon in tension, although other ways of tensioning the outer conductive layer 20 are possible. While the outer conductive layer 20 is tensioned and the air gap 36 is maintained, it is not necessary to control the tension of the outer conductive layer 20 as precisely as where the resistive layer 18 is omitted. Because the resistive layer 18 provides a large resistivity in the quiescent state, incidental contact between the resistive layer 18 and the inner conductive layer 16 does not result in a false touch being registered. In some cases, a certain amount of slack in the outer flexible layer 22 may provide increased tactility to the whiteboard 10.

Referring now to FIG. 1C, there is shown an alternative embodiment of the whiteboard 10 shown in FIG. 1B. In this alternative embodiment, the resistive layer 18 is in contact with the outer surface 30 of the inner conductive layer 16, as opposed to the inner surface 32 of the outer conductive layer 32 shown in FIG. 1B.

During assembly of the whiteboard 10, the inner conductive layer 16 may be applied to the inner flexible layer 14 and the outer conductive layer 20 may be applied to the outer flexible layer 22. A resistive layer 18 may then applied to one or both of the conductive layers. An air gap 36 may be formed as exemplified in FIGS. 1B and 1C as may be desired.

Referring now to FIG. 2, the embodiment of the whiteboard 10 having no air gap is shown in enlarged portion. In particular, the inner conductive layer 16 and the outer conductive layer 20 are shown having thickness. It should be appreciated that the dimension shown in FIG. 2 may be exaggerated for purpose of illustration.

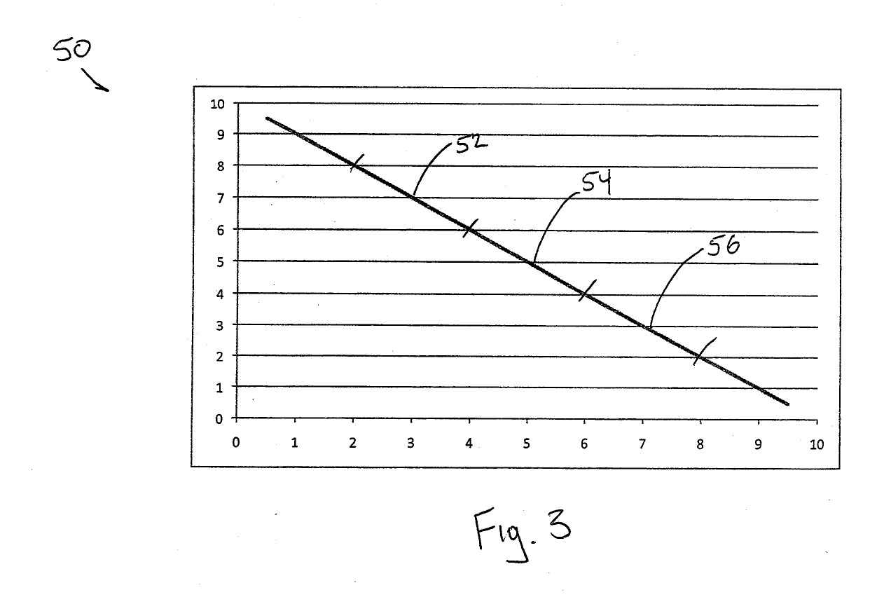

Referring now to FIG. 3, there is shown a graph 50 illustrating an exemplary relationship between resistivity and applied pressure. The graph 50 is shown with arbitrary units and, it should be appreciated, can also be plotted on different scales. For example, the graph 50 represents the resistivity of the resistive layer 18 (FIGS. 1A-1C) under mechanical deformation and/or mechanical stress, such as caused by application of pressure or other mechanical forces.

As can be seen in FIG. 3, the resistivity of the resistive layer 18 may vary inversely with applied pressure or some other stimulus causing mechanical deformation of the resistive layer 18. Preferably, for low applied pressures, the resistivity becomes very large and the resistive layer 18 behaves like an insulator. However, for increasing applied pressure, the resistivity of the resistive layer 18 decreases, preferably monotonically, causing the resistive layer 18 to behave like an increasingly efficient conductor.

Different ranges of applied pressure correspond to different ranges of the resistivity of the resistive layer 18. Range 52 in FIG. 3, which is defined between about 6 and 8 on the y-axis, corresponds to an applied pressure of between about 2 and 4 on the x-axis. Likewise range 54 corresponds to progressively larger force applied to the resistive layer 18 (i.e. about 4 to 6) and range 56 to still larger forces (i.e. about 6 to 8). These ranges may be non-overlapping and, in a particular, case, contiguous. A linear relation is illustrated in FIG. 3 as one exemplary relationship. However, in some embodiments, the resistivity of the resistive layer 18 may have a convex or a concave slope with increasing applied pressure.

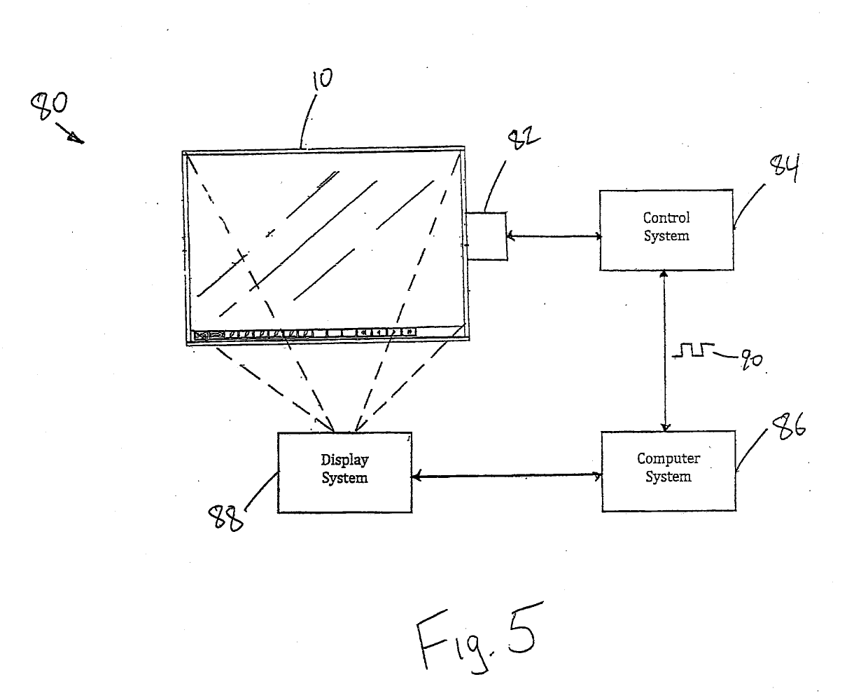

By measuring the resulting resistivity of the resistive layer 18, the amount of the applied pressure is measurable. The variable resistivity of the resistive layer 18 provides the basis for progressive touch capability for the whiteboard 10. For example, different input commands may be defined based on the degree of the applied pressure. As will be explained more with reference to FIG. 5, the different input commands may be generated for a display system linked to the whiteboard via an intermediate computer system to manipulate images displayed on the whiteboard 10 or some other secondary display of the computer system.

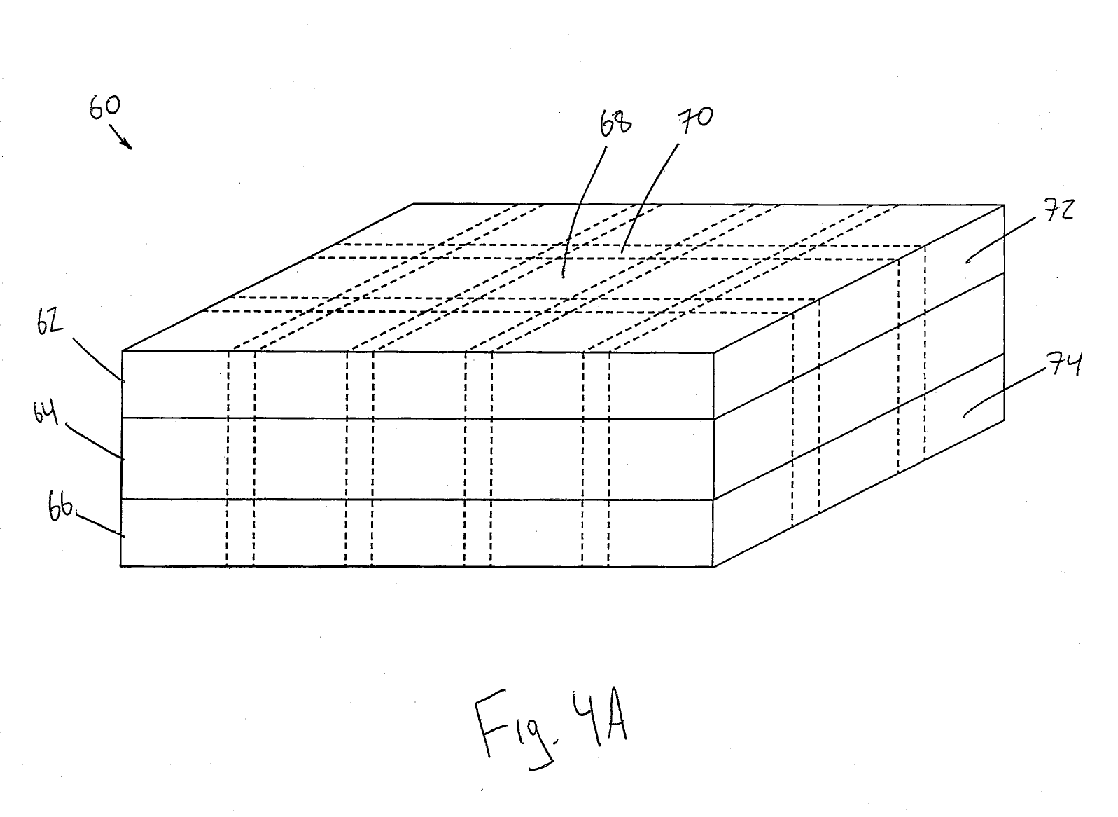

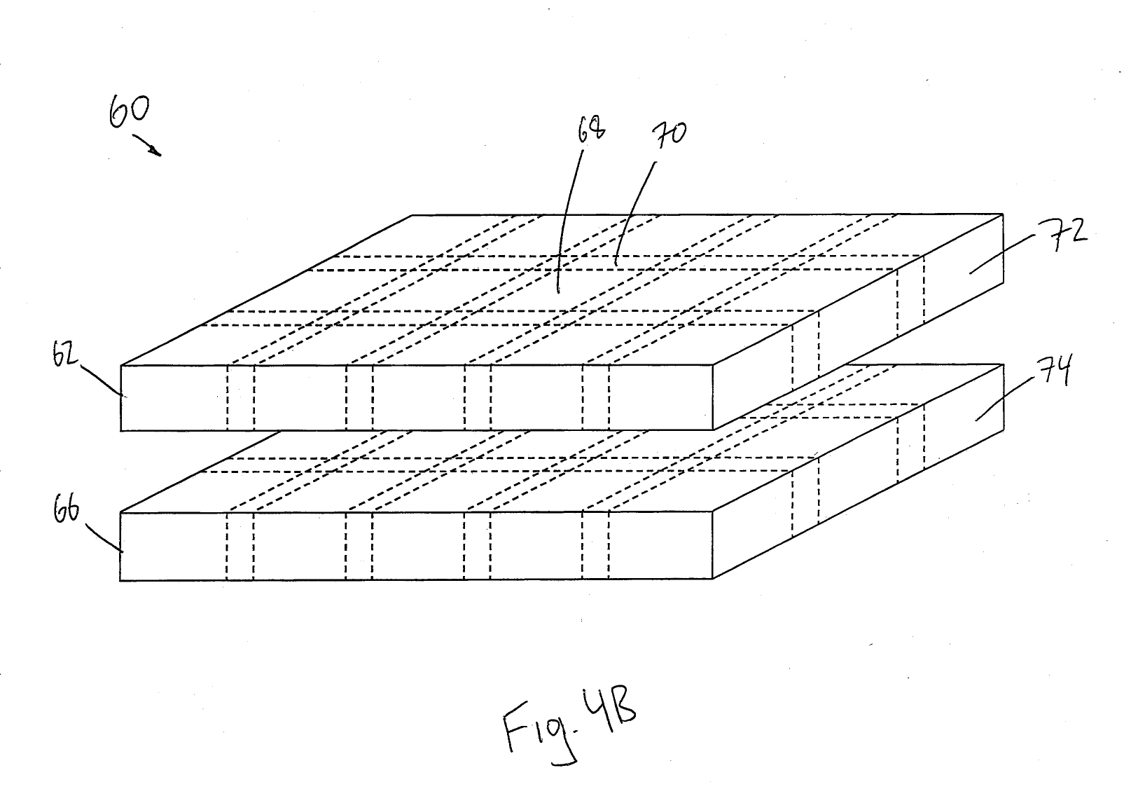

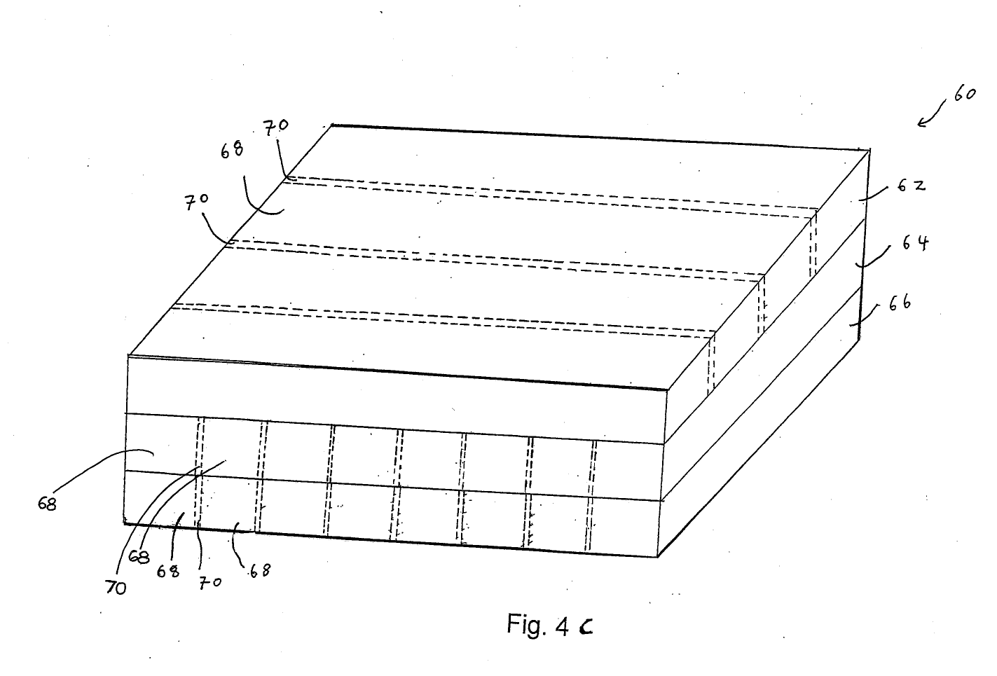

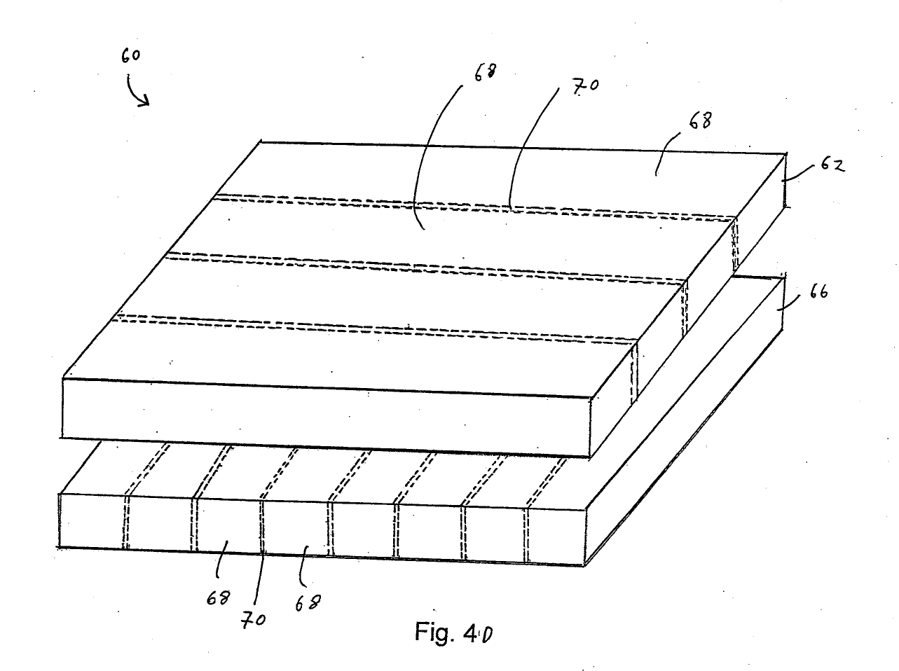

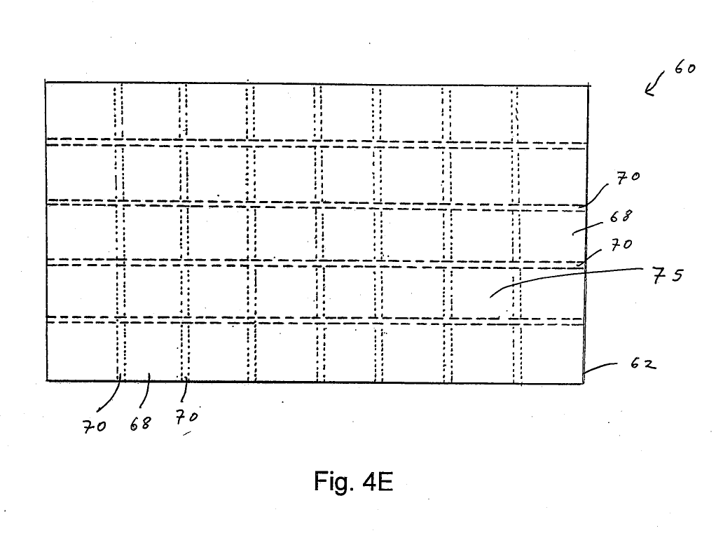

Referring now to FIGS. 4A and 4B, there is illustrated a portion of a whiteboard 60, which may be of any embodiment discussed with respect to FIGS. 1A-1C. FIG. 4B shows the whiteboard 60 of FIG. 4A, but with the resistive layer 64 omitted for clarity of illustration. The whiteboard 60 has an outer conductive layer 62, resistive layer 64 and inner conductive layer 66, each of which is divided into a plurality of planar segments 68 in a grid like formation that enables multi-touch functionality for the whiteboard 60 as follows. The planar segments 68 are shown having a square shape, although optionally in some embodiments other shapes may be used for the planar elements 68, such as rectangles or diamonds, to provide the grid.

The outer conductive layer 62 is formed into a plurality of planar segments 68, where each planar segment 68 is preferably in close proximity to adjacent planar segments 68, but is electrically insulated from the adjacent planar segments 68 using a suitable insulating barrier 70, which may be provided by as an insulating material, an air gap (e.g., a portion in which the conductive layer is not provided such as a break in the printing of the conductive layer) or some other arrangement resulting in the absence of conductive material between planar segments. The planar segments 68 may be formed into a two-dimensional grid, as illustrated, having, preferably, a regular grid spacing.

The inner conductive layer 66 is similarly formed into a plurality of planar segments 68, so that the planar segments of the lower conductive layer 66 are opposed to and generally aligned with the planar segments of the upper conductive layer 62 according to the same spacing. Thereby, the planar segments in the outer and inner conductive layers 62 and 66 face towards each other and form coupled pairs. Planar segments 72 and 74 are one such aligned pair.

The resistive layer 64 sandwiched between the inner and outer conductive layers 62 and 66 may also be divided into a plurality of planar segments in the same regular grid spacing. Since each planar segment in the inner and outer conductive layers 62 and 66 forms an independent conductive path through the resistive layer 64, the whiteboard 60 provides locally detectable variation in the resistivity of the resistive layer 64, i.e. because each planar segment triplet may have its own effective resistive and forms an independent path.

In this way, multiple applications of the force causing mechanical deformation of the resistive layer 64 are concurrently detectable. In other words, the whiteboard 60 may receive multi-touch input commands, such as for manipulating the display images on the whiteboard 60 as now described.

Referring now to FIGS. 4C, 4D and 4E, there is illustrated a portion of an alternate whiteboard 60, which may be of any embodiment discussed with respect to FIGS. 1A-1C. FIG. 4D shows the whiteboard 60 of FIG. 4C, but with the resistive layer 64 omitted for clarity of illustration. The whiteboard 60 has an outer conductive layer 62, resistive layer 64 and inner conductive layer 66, each of which is divided into a plurality of planar segments 68 set out as a plurality of strips that enables multi-touch functionality for the whiteboard 60 as follows. The planar segments 68 are shown having a rectangular shape, although optionally in some embodiments other shapes may be used for the planar elements 68.

The outer conductive layer 62 is formed into a plurality of planar segments 68, where each planar segment 68 is preferably in close proximity to adjacent planar segments 68, but is electrically insulated from the adjacent planar segments 68 using a suitable insulating barrier 70, which may be provided by as an insulating material, an air gap or some other arrangement resulting in the absence of conductive material between planar segments. The planar segments 68 preferably are regularly spaced.

The resistive layer 64 is similarly formed into a plurality of planar segments 68, which are preferably aligned with the segments 68 of one of the outer conductive layer 62 and the inner conductive layer 66 and, more preferably as exemplified, the inner conductive layer 66.

The inner conductive layer 66 is similarly formed into a plurality of planar segments 68, which preferably extend in an alternate direction to the planar segments of outer conductive layer 62 and may be perpendicular thereto. Thereby, the planar segments in the outer and inner conductive layers 62 and 66 face towards each other and, when viewed from above, form a grid wherein the grid pieces may be in the shape of squares, rectangles or diamonds, Accordingly, the outer and inner conductive layers 62 and 66 are configured to define a grid when in a superimposed position. As exemplified, grid pieces 75 are in the shape of squares.

Since each planar segment 68 in the inner and outer conductive layers 62 and 66 form an independent conductive path through the resistive layer 64, the whiteboard 60 provides locally detectable variation in the resistivity of the resistive layer 64.

In this way, multiple applications of the force causing mechanical deformation of the resistive layer 64 are concurrently detectable. In other words, the whiteboard 60 may receive multi-touch input commands, such as for manipulating the display images on the whiteboard 60 as now described.

In an exemplary embodiment, only two segments 68 may be provided in each layer. For example, the outer conductive layer 62 may have a single vertical insulating barrier 70 thereby dividing a whiteboard 60 into a left side portion and a right side portion. A first user may use the left side of whiteboard 60 and, concurrently, a second user may use the right side of whiteboard 60. Accordingly, whiteboard 60 may be a multiuser board.

Referring now to FIG. 5, there is shown an interactive whiteboard system 80 in accordance with preferred embodiments. The interactive whiteboard system 80 includes a whiteboard, which may be whiteboard 10 (or alternatively the whiteboard 60 shown in FIGS. 4A and 4B or in FIGS. 4C-4E), an output connection 82, a control system 84, a computer system 86 and an optional display system 88 associated with the computer system 86. The display system 88 may be a projector set up to project an image on to whiteboard 10, as exemplified, and/or it may be a computer monitor.

The control system 84 is coupled to the whiteboard 10, via the output connection 82, and is used to detect touches to the surface of the whiteboard 10, which may be a pressure sensitive composite layer such as is shown in FIGS. 1A-1C. Based on the type of touch, the control system generates different input commands 90 for the computer system 86, such as input commands for manipulating images displayed by the display system 88 on the whiteboard 10 or some other display associated with the computer system 86. For example, the computer system 86 may be a laptop or desktop computer with its own display.

The control system 84 generates one or more different types of input commands 90 for the display system 88 based on the nature of the pressure applied to the contact surface of the whiteboard 10. The types of inputs commands 90 for the display system 88 are not limited, and one or more of each of the following commands 90 may be defined.

The control system may define and generate a navigate command used to move a cursor or other icon that is displayed, e.g., on the whiteboard 10, by the display system 88. For example, the cursor may be moved corresponding to the movement of the applied pressure to the whiteboard that is registered by sensing changes in the electrical resistivity of the resistive layer 18 (FIGS. 1A-1C). In this way, the whiteboard 10 may be used as a large track pad or touch screen for controlling the computer system 86.

Typically, interactive whiteboards are constructed such that a command is initiated simultaneous with touch. There is no feedback system that advises a user where the touch will occur and accordingly which command will be executed. An advantage of this embodiment is provides a “hover” functionality to whiteboards, such as when a user lightly touches the surface. Accordingly, a user will be given information about what will happen when a command is executed,

Additionally, the control system may define and generate an execute command used to initiate supplemental commands and other actions in the computer system 86. For example, the execute command may be used as a primary selection device (analogous to a left mouse click on a conventional mouse) for manipulating objects displayed on the whiteboard 10 by the display system.

In addition to the execute command, the control system 84 may define an activate command used by the display system 88 to generate supplemental graphics on the whiteboard superimposed onto the display image. These supplemental graphs may include such things as a text box showing additional information about one or more displayed objects, as well as a menu displaying and enabling supplemental image manipulation commands. In this way, the activate command may be analogous to a right mouse click on a conventional mouse, or a navigate-and-pause to hover action.

For an intuitive interactive experience, the navigate command is preferably entered by applying a first level of pressure to the surface of the whiteboard 10. A range of different pressures is preferably defined within which the navigate command is defined. In some embodiments, the range of pressures may be user-defined similar to user-defined mouse settings like click or scroll speed. The first level of pressure preferably requires a minimum amount of pressure. Accordingly, until an initial level of pressure is applied, no functionality will be initiated. Any contact that applies less than the minimum amount of pressure will essentially be ignored.

A next level of pressure greater than that corresponding to the navigate command is preferably used to input the activate command, and a still greater level of pressure is preferably used for the execute command. This way, users of the whiteboard 10 may scroll around the display image with a light touch and then take further action by increasing the pressure of the applied touch. Alternately, the next level of pressure may be used to execute a command and there may not be an activate level of pressure. Accordingly, a user may release and then tap the same location to execute a command or they may merely press harder without releasing, once at the desired location.

Alternately, or in addition to progressive touch input commands, the interactive whiteboard system 80 preferably supports multi-touch commands when the whiteboard 60 is included. For example, not just the relative pressure of each applied touch may be detected, but also the number and location of each concurrently applied touch. This allows for the whiteboard 60 to detect different input gestures, which are then translated into different multi-touch input commands by the control system 84.

Accordingly, in some embodiments, the control system 84 may generate the input commands for the computer system 86 by also determining one or more of the number of concurrently applied touches, the relative spacing of the concurrent touches, relative movement (i.e. toward, away from, parallel to) between concurrent touches. The control system 84 may also generate gesture input commands by further determining different degrees of applied pressure in each of the concurrent touches, such as a light touch in one quadrant of the whiteboard 60 and a concurrent heavy touch in another quadrant.

The different ways of manipulating the display image are not limited to just the described examples. In some embodiments, the input commands 90 may be used to vary a thickness or color of a drawing tool. Alternately or in addition, in some embodiments, the input commands 90 may select between different layers of a composite image, i.e. by bringing a select layer of the image to the forefront of the display based on the strength of the applied touch.

It will be appreciated by those skilled in the art that any of the aspects of this invention may be combined in any combination or sub combinations and that not all aspects need be incorporated into a single embodiment.

1. A dry erase whiteboard comprising:
a) a backing substrate having a surface;
b) spaced apart inner and outer conductive layers, the inner conductive layer supported by the surface of the substrate; and
c) a resistive layer positioned between the inner conductive layer and the outer conductive layer, the resistive layer having an electrical resistivity that varies in response to mechanical deformation or stress, the resistive layer providing a variable effective resistance between the inner and outer conductive layers.

2. The whiteboard of claim 1, further comprising a frame secured to the backing substrate, the frame having a plurality of frame members that are positioned on the backing substrate.

3. The whiteboard of claim 2, wherein the outer conductive layer is secured to the frame in spaced apart relation to the resistive layer such that an air gap is provided between the resistive layer and the outer conductive layer.

4. The whiteboard of claim 1, further comprising a frame secured to the backing substrate, the outer conductive member is mounted to the frame and the frame comprises a plurality of frame members and a tensioning assembly.

5. The whiteboard of claim 4, wherein the outer conductive layer is provided on an inner surface of a flexible substrate that is mounted tautly to the frame.

6. The whiteboard of claim 1, wherein the resistive layer is provided on at least one of an outer surface of the inner conductive layer and an inner surface of the outer conductive layer.

7. The whiteboard of claim 1, wherein the resistive layer is provided on each of an outer surface of the inner conductive layer and an inner surface of the outer conductive layer such that a substantially air-free environment is provided between the inner conductive layer and the outer conductive layer.

8. The whiteboard of claim 7, further comprising an adhesive layer between the resistive layer and one of the inner conductive layer and the outer conductive layer.

9. The whiteboard of claim 1, wherein the electrical resistivity of the resistive layer varies inversely with the mechanical deformation or stress.

10. The whiteboard of claim 1, further comprising an inner flexible substrate and an outer flexible substrate, wherein an inner surface of the inner conductive layer is provided on an outer surface of the inner flexible substrate, and an outer surface of the outer conductive layer is provided on an inner surface of the outer flexible substrate.

11. The whiteboard of claim 10, wherein the inner flexible substrate is secured to the surface of the substrate.

12. The whiteboard of claim 1, wherein each conductive layer comprises a plurality of planar segments, each planar segment in close proximity to and electrically insulated from adjacent planar segments providing locally detectable variation in the effective resistance between the inner and outer conductive layers.

13. The whiteboard of claim 12, wherein the plurality of planar segments in the inner and outer conductive layers are configured to define a grid when in a superimposed position.

14. A method of assembling a dry erase whiteboard, comprising:
a) providing an inner conductive layer;
b) providing an outer conductive layer;
c) applying a resistive layer to at least one of the inner conductive layer and the outer conductive layer, the resistive layer formed from a material having an electrical resistivity that varies in response to mechanical deformation or stress; and,
d) securing the inner and outer conductive layers in position with the inner and outer conductive layers facing each other.

15. The method of claim 14, wherein step (d) comprises:
a) mounting the inner conductive layer on a surface of the backing substrate; and,
b) mounting the outer conductive layer to a frame in close proximity to the first conductive layer, the frame comprising a plurality of frame members that are connected together, whereby an effective resistance between the inner and outer conductive layers is variable with the mechanical deformation or stress of the resistive layer.

16. The method of claim 15, further comprising mounting the outer conductive layer to the frame in spaced apart relation to the inner conductive layer whereby an air gap is provided therebetween.

17. The method of claim 16, wherein the outer conductive layer is provided on an outer flexible substrate and the method further comprises tensioning the outer flexible substrate prior to mounting the outer flexible substrate to the frame.

18. The method of claim 14, further comprising mounting the outer conductive layer to a frame in spaced apart relation to the inner conductive layer whereby an air gap is provided therebetween.

19. The method of claim 14, further comprising providing the resistive layer onto one of the inner conductive layer and the outer conductive layer.

20. The method of claim 14, further comprising screen-printing the resistive layer onto one of the inner conductive layer and the outer conductive layer.

21. The method of claim 19, further comprising adhering the resistive layer to the other of the inner conductive layer and the outer conductive layer whereby a substantially air free environment is provided between the inner conductive layer and the outer conductive layer.

22. The method of claim 14, further comprising providing the inner conductive layer on an inner flexible substrate and the outer conductive layer on an outer flexible substrate.

23. The method of claim 22, further comprising providing each conductive layer onto the corresponding flexible substrate.

24. The method of claim 22, further comprising screen-printing each conductive layer onto the corresponding flexible substrate.

25. The method of claim 14, further comprising forming each conductive layer into a plurality of planar segments, each planar segment in close proximity to and electrically insulated from adjacent planar segments to provide locally detectable variation in the effective resistance between the inner and outer conductive layers.

26. The method of claim 25, further comprising configuring the plurality of planar segments in the inner and outer conductive layers to define a grid when in a superimposed position.
